(19) United States
(12) Patent Application Publication
(10) Pub. No.: US 2023/0260934 A1
(43) Pub. Date: Aug. 17, 2023

(54) PLASMA DAMAGE PROTECTION DEVICE AND PLASMA DAMAGE PROTECTION METHOD

(71) Applicant: Winbond Electronics Corp., Taichung City (TW)

(72) Inventors: Chao-Lung Wang, Taichung City (TW); Jhih-Chun Syu, Taichung City (TW)

(73) Assignee: Winbond Electronics Corp., Taichung City (TW)

(21) Appl. No.: 17/671,551

(22) Filed: Feb. 14, 2022

(51) Int. Cl. H01L 23/62; H01L 23/525

(52) U.S. Cl. CPC H01L 23/62; H01L 23/5256; H01L 23/5252

(57) ABSTRACT

Disclosed are a plasma damage protection device and a plasma damage protection method. The plasma damage protection device is disposed in an integrated circuit. The plasma damage protection device includes a switch component and a transmission structure. The switch component is coupled between a reference power rail and a pad. The switch component is turned on or cut off according to a charge on the pad. The pad is coupled to a protected component. The transmission structure is configured to transmit the charge on the pad to a control end of the switch component during a back-end-of-line process. The switch component is turned on according to the charge on the pad during the back-end-of-line process.

### BACKGROUND

### Technical Field

The disclosure relates to a plasma damage protection device and a plasma damage protection method. In particular, the disclosure relates to a plasma damage protection device and a plasma damage protection method that achieve bipolar protection.

### Description of Related Art

In a semiconductor manufacturing process, in an etching process, for example, it is often necessary to apply plasma in an integrated circuit. Charges brought by the applied plasma may be accumulated in a circuit component and damage the same.

In conventional technology, a diode is often disposed beside a protected component for protection against plasma damage. Such a diode typically protects against only unipolar charges. Therefore, in conventional technology, bipolar protection against plasma damage is also achieved by disposing a bipolar transistor. However, the protection against plasma damage achieved by the bipolar transistor does not exhibit good performance in protection against charges of whichever of positive polarity or negative polarity. Therefore, it is an issue to be addressed by designers in this field to propose a high-performance plasma damage protection device.

### SUMMARY

The disclosure provides a plasma damage protection device and a plasma damage protection method, which improves protection performance against plasma damage generated during a manufacturing process.

According to an embodiment of the disclosure, a plasma damage protection device is disposed in an integrated circuit. The plasma damage protection device includes a switch component and a transmission structure. The switch component is coupled between a reference power rail and a pad. The switch component is turned on or cut off according to a charge on the pad. The pad is coupled to a protected component. The transmission structure is configured to transmit the charge on the pad to a control end of the switch component during a back-end-of-line process. The switch component is turned on according to the charge on the pad during the back-end-of-line process.

According to an embodiment of the disclosure, a plasma damage protection method includes the following. A transmission structure is formed to be coupled to a pad. A switch component is formed to be coupled to the transmission structure, a protected component, the pad, and a reference power rail. A charge on the pad is transmitted to a control end of the switch component by the transmission structure and the switch component is turned on according to the charge on the pad during a back-end-of-line process.

Based on the foregoing, during the back-end-of-line process of the disclosure, the charge on the pad is transmitted to the control end of the switch component through the provided transmission structure, and the charge on the pad is dissipated by turning on the switch component, accordingly preventing components in the integrated circuit from damage by the accumulated charge of the plasma on the pad, and maintaining reliability of the integrated circuit.

To make the aforementioned more comprehensible, several embodiments accompanied with drawings are described in detail as follows.

### BRIEF DESCRIPTION OF THE DRAWINGS

FIG. 1 is a schematic diagram of a plasma damage protection device according to an embodiment of the disclosure.

FIG. 2 is a schematic diagram of a plasma damage protection device according to another embodiment of the disclosure.

FIG. 3A and FIG. 3B are schematic diagrams of operations of a plasma damage protection device 200 according to the embodiment of FIG. 2 of the disclosure.

FIG. 4 is a schematic diagram of a plasma damage protection device during a back-end-of-line process according to an embodiment of the disclosure.

FIG. 5 is a flowchart of a plasma damage protection method according to an embodiment of the disclosure.

### DESCRIPTION OF THE EMBODIMENTS

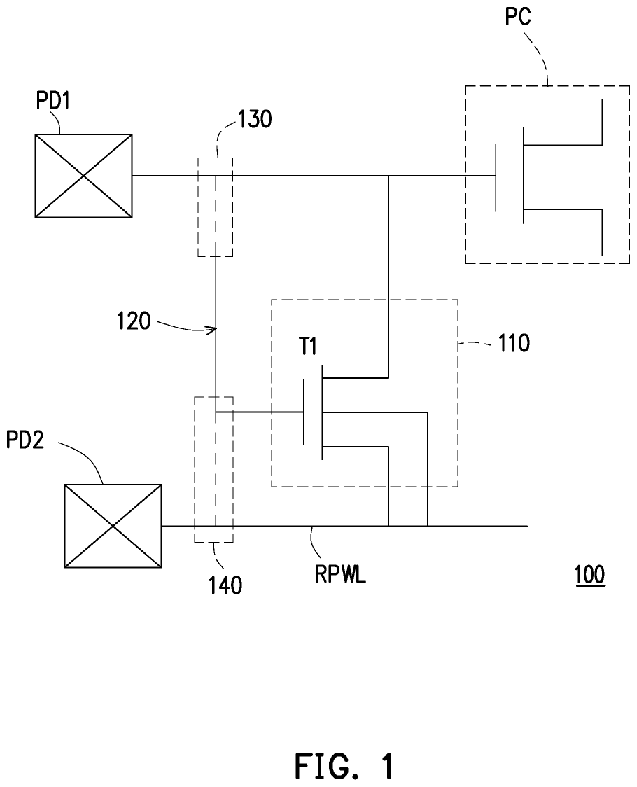

With reference to FIG. 1, a plasma damage protection device 100 includes a switch component 110 and a transmission structure 120. The switch component 110 is coupled between a reference power rail RPWL and a pad PD1. The switch component 110 is turned on or cut off according to a charge on the pad PD1. The pad PD1 is coupled to a protected component PC. The protected component PC may be a transistor or any other type of semiconductor component. The transmission structure 120 is coupled to the switch component 110 and the reference power rail RPWL. In this embodiment, the transmission structure 120 may be coupled to the pad PD1 through a connection structure 130.

In this embodiment, during a back-end-of-line (BEOL) process, the transmission structure 120 may remain coupled to the pad PD1 through the connection structure 130, so that the charge on the pad PD1 may be transmitted to a control end of the switch component 110 through the transmission structure 120. The switch component 110 is a transistor T1. A first end of the transistor T1 is connected to the pad PD1, a second end and a base end of the transistor T1 are jointly coupled to the reference power rail RPWL, and the control end of the transistor T1 is coupled to the transmission structure 120.

It is worth mentioning that the switch component 110 may be turned on or cut off according to the charge on the pad PD1. During the manufacturing process, when the accumulated charge of applied plasma on the pad PD1 exceeds an expected amount, the switch component 110 may be turned on to accordingly dissipate the charge on the pad PD1 to the reference power rail RPWL, and prevent the protected component PC from damage caused by the excessive charge on the pad PD1.

Incidentally, the reference power rail RPWL may be coupled to a pad PD2. The reference power rail RPWL may receive a reference voltage through the pad PD2.

In addition, in this embodiment, the connection structure 130 may be removed after the back-end-of-line process is completed. Moreover, a transmission wire 140 may be formed between the control end of the switch component 110 and the reference power rail RPWL. The transmission wire 140 is configured to pull down a voltage on the control end of the switch component 110 to the reference voltage on the reference power rail RPWL. Accordingly, the transistor T1 in the switch component 110 can be maintained in a cut-off state.

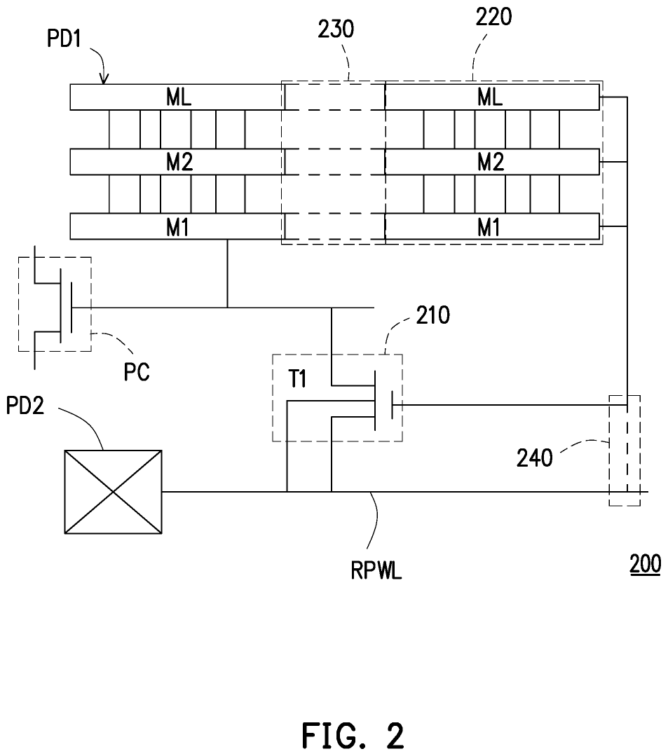

With reference to FIG. 2, a plasma damage protection device 200 includes a switch component 210 and a transmission structure 220. The switch component 210 is constructed by the transistor T1. The transistor T1 is coupled between the pad PD1 and the reference power rail RPWL, and the control end of the transistor T1 is coupled to the transmission structure 220. In this embodiment, the pad PD1 is composed of a metal layer ML. The metal layer ML and metal layers M1 and M2 may be coupled to each other, and the metal layer M1 may be directly connected to the transistor T1 and the protected component PC.

In addition, the transmission structure 220 is formed in at least one metal layer. In an embodiment, the transmission structure 220 may be formed by the metal layers ML, M2, and M1. The metal layers ML, M2, and M1 are sequentially coupled. Moreover, before the back-end-of-line process is completed, the transmission structure 220 may be coupled to the pad PD1 through a connection structure 230. The connection structure 230 and the transmission structure 220 may be constructed utilizing the same metal layers ML, M2, and M1.

During the back-end-of-line process, the charge on the pad PD1 may be conducted to the control end of the transistor T1 through the connection structure 230 and the transmission structure 220. If the charge on the pad PD1 exceeds a certain threshold, the transistor T1 may accordingly be turned on and form a conduction path between the pad PD1 and the reference power rail RPWL. Through the conduction path provided by the transistor T1, the charge on the pad PD1 can be effectively dissipated, and the protected component PC can be prevented from damage caused by the charge on the pad PD1.

In this embodiment, the reference power rail RPWL is coupled to the pad PD2 and may receive a reference voltage.

Moreover, the connection structure 230 may be removed after the back-end-of-line process is completed. Furthermore, a transmission wire 240 may be formed between the control end of the transistor T1 and the reference power rail RPWL. The transmission wire 240 is configured to transmit the reference voltage on the reference power rail RPWL to the control end of the transistor T1 to maintain the transistor T1 in a cut-off state.

Incidentally, the numbers of the metal layers of the pad PD1, the connection structure 230, and the transmission structure 220 formed in this embodiment are not particularly limited. The illustration of FIG. 2 is only an example for description, and is not intended to limit the scope of the disclosure.

In addition, the transistor T1 may be an N-type metal-oxide-semiconductor field effect transistor.

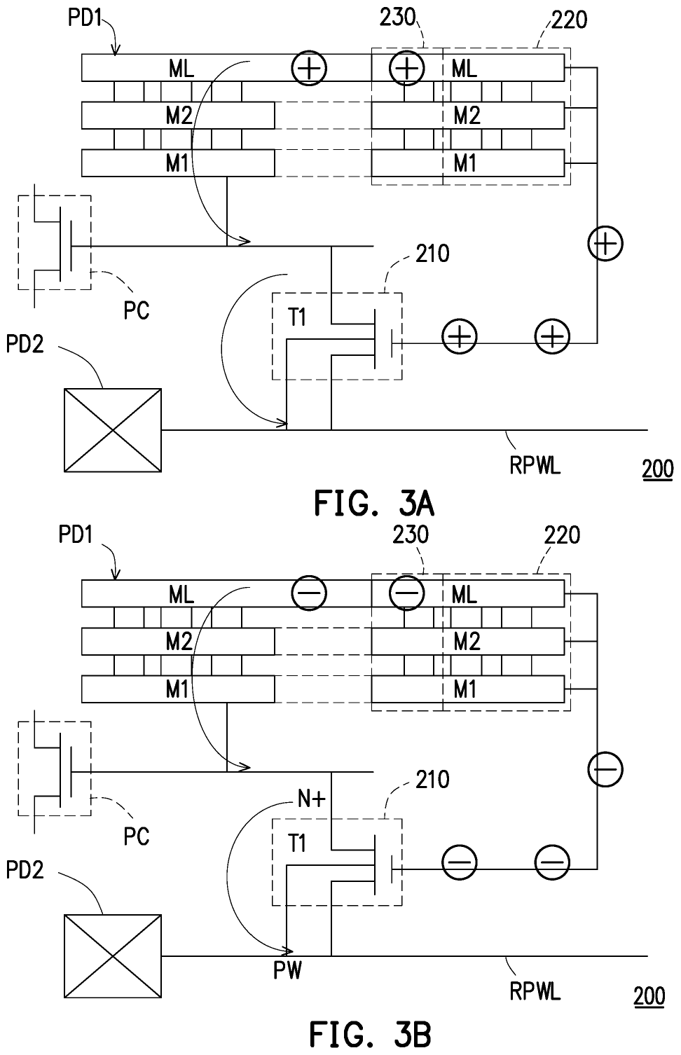

With reference to FIG. 3A, when the applied charge of the plasma is a positive charge and is remained on the pad PD1, the connection structure 230 and the transmission structure 220 connected to each other through the metal layer ML may transmit the positive charge on the pad PD1 to the control end of the transistor T1. On the basis that the transistor T1 is an N-type transistor, the transistor T1 may be turned on according to the positive charge on the control end thereof. Under this circumstance, the turned-on transistor T1 may form a channel between the pad PD1 and the reference power rail RPWL, so that the charge on the pad PD1 may be dissipated by the second end of the transistor T1 through the channel formed by the transistor T1.

Accordingly, an excessive amount of positive charge may not be accumulated on the gate of the protected component PC (e.g., a transistor), the possibility of burning out the protection component PC can be effectively reduced, and normal operation of the integrated circuit is maintained.

Note here that, during manufacturing of the metal layers M1, the metal layers M1 in the pad PD1, in the connection structure 230, and in the transmission structure 220 are connected to each other. After the manufacturing of the metal layers M1 and during a manufacturing process of the metal layers M2, the part of the metal layer M1 in the connection structure 230 may be removed, and the metal layers M1 in the pad PD1 and in the transmission structure 220 may be disconnected from each other. Similarly, during manufacturing of the metal layers M2, the metal layers M2 in the pad PD1, in the connection structure 230, and in the transmission structure 220 are connected to each other. After the manufacturing of the metal layers M2 and during a manufacturing process of the metal layers ML, the part of the metal layer M2 in the connection structure 230 may be removed, and the metal layers M2 in the pad PD1 and in the transmission structure 220 may be disconnected from each other.

With reference to FIG. 3B, when the applied charge of the plasma is a negative charge and is remained on the pad PD1, the connection structure 230 and the transmission structure 220 connected to each other through the metal layer ML may transmit the negative charge on the pad PD1 to the control end of the transistor T1. On the basis that the transistor T1 is an N-type transistor, an N-type heavily doped region (N+) is on the first end of the transistor T1, and the transistor T1 may have a base end of a P-type well region. Therefore, when the negative charge is received on the control end of the transistor T1, a P-N junction between the base end and the first end of the transistor T1 may be turned on and form a channel. Under this circumstance, the negative charge on the pad PD1 may be dissipated by the base end of the transistor T1 through the channel formed by the transistor T1, and the protected component PC can be prevented from being burned out because of the negative charge accumulated on the gate.

As shown from the embodiments of FIG. 3A and FIG. 3B, the plasma damage protection device 200 can effectively provide a charge dissipation path for whichever of positive charge or negative charge generated by the plasma and achieve plasma damage protection.

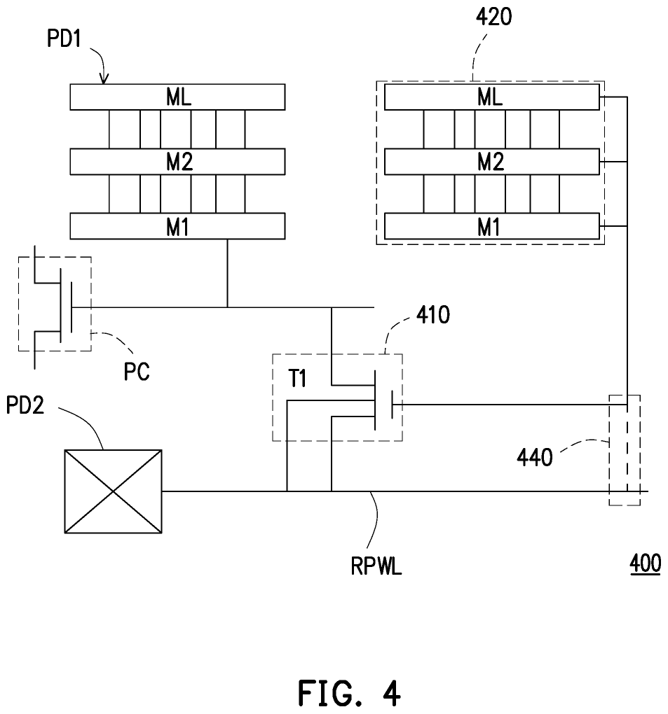

With reference to FIG. 4, in the integrated circuit, after the back-end-of-line process is completed, a plasma damage protection device 400 includes a switch component 410, a transmission structure 420, and a transmission wire 440. The switch component 410 includes the transistor T1. The transistor T1 may be an N-type transistor coupled between the reference power rail RPWL and the pad PD1. The control end of the transistor T1 may be coupled to the transmission structure 420 and the transmission wire 440. The transmission wire 440 is connected between the reference power rail RPWL and the transmission structure 420. When the reference power rail RPWL receives a reference voltage (e.g., a reference ground voltage), the transmission wire 440 is configured to transmit the reference voltage to the control end of the transistor T1. Under this circumstance, the transistor T1 may be cut off according to the received reference voltage.

It is worth mentioning that in this embodiment, the pad PD1 and the transmission structure 420 are physically isolated from each other. After the back-end-of-line process is completed, the connection structure configured to connect the pad PD1 and the transmission structure 420 has been removed. Accordingly, during normal operation of the integrated circuit, the voltage applied on the pad PD1 may not be affected by the transmission structure 420 and the transistor T1, maintaining normal operation of the protected component PC.

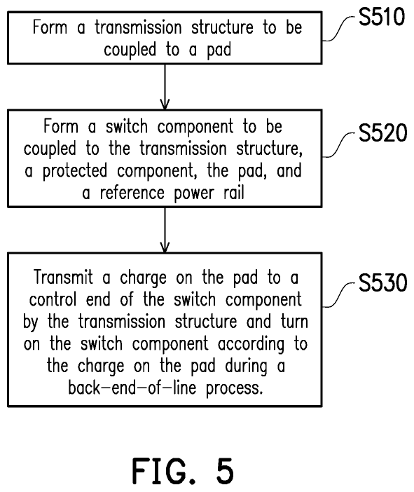

FIG. 5 is a flowchart of a plasma damage protection method according to an embodiment of the disclosure. In step S510, in an integrated circuit, a transmission structure is formed to be coupled to a pad. In step S520, a switch component is formed to be coupled to the transmission structure, a protected component, the pad, and a reference power rail. Next, in step S530, during a back-end-of-line process, the transmission structure transmits a charge on the pad to the control end of the switch component, and the switch component is turned on according to the charge on the pad. After the switch component is turned on, the charge on the pad may be dissipated through the turned-on switch component, effectively preventing the protected component in the integrated circuit from damage by the accumulated charge on the pad.

The implementation specifics of the above-mentioned steps have been described in detail in the above-mentioned multiple embodiments, and will not be repeatedly described here.

In summary of the foregoing, in the plasma damage protection device of the disclosure, during the back-end-of-line process, the transmission structure is provided to transmit the charge on the pad, and the switch component is provided to be turned on according to the charge on the pad transmitted by the transmission structure. Through the turned-on switch component, the accumulated charge on the pad can be effectively dissipated, and plasma damage protection can be achieved. In the embodiments of the disclosure, the switch component may be turned on corresponding to the charge of whichever polarity, achieving bipolar protection. It is worth mentioning that after the back-end-of-line process of the plasma damage protection device of the disclosure is completed, the connection between the transmission structure and the pad may be cut off, so that the plasma damage protection device may not affect the normal operation of the integrated circuit.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A plasma damage protection device, disposed in an integrated circuit, and comprising:
a switch component coupled between a reference power rail and a pad, and being turned on or cut off according to a charge on the pad, wherein the pad is coupled to a protected component; and
a transmission structure configured to transmit the charge on the pad to a control end of the switch component during a back-end-of-line process,
wherein the switch component is turned on according to the charge on the pad during the back-end-of-line process.

2. The plasma damage protection device according to claim 1, further comprising:
a connection structure configured to connect the pad and the transmission structure, wherein the connection structure is removed after the back-end-of-line process.

3. The plasma damage protection device according to claim 1, wherein the switch component comprises:
a transistor having a first end coupled to the pad, a control end coupled to the transmission structure, and a second end and a base end each coupled to the reference power rail.

4. The plasma damage protection device according to claim 3, wherein the transistor is an N-type transistor, and when the charge on the pad has a positive polarity, the transistor is turned on according to the charge on the pad on the control end.

5. The plasma damage protection device according to claim 3, wherein the transistor is an N-type transistor, and when the charge on the pad has a negative polarity, a P-N junction formed between the base end of the transistor and the first end of the transistor is turned on.

6. The plasma damage protection device according to claim 1, wherein the transmission structure is formed in at least one metal layer.

7. The plasma damage protection device according to claim 1, further comprising:
a transmission wire configured to be connected between the reference power rail and the control end of the switch component after the back-end-of-line process.

8. A plasma damage protection method, comprising:
forming a transmission structure to be coupled to a pad;
forming a switch component to be coupled to the transmission structure, a protected component, the pad, and a reference power rail; and
transmitting a charge on the pad to a control end of the switch component by the transmission structure and turning on the switch component according to the charge on the pad during a back-end-of-line process.

9. The plasma damage protection method according to claim 8, further comprising:
forming a connection structure to connect the switch component and the transmission structure.

10. The plasma damage protection method according to claim 9, further comprising:
removing the connection structure after the back-end-of-line process.

11. The plasma damage protection method according to claim 10, further comprising:
forming a transmission wire to be connected between the reference power rail and the control end of the switch component after the back-end-of-line process.

12. The plasma damage protection method according to claim 8, wherein the switch component is a transistor.

13. The plasma damage protection method according to claim 12, further comprises:
when the charge on the pad has a positive polarity, turning on the transistor according to the charge on the pad on the control end.

14. The plasma damage protection method according to claim 12, further comprising:
when the charge on the pad has a negative polarity, turning on a P-N junction formed between a base end of the transistor and a first end of the transistor.

15. The plasma damage protection method according to claim 12, wherein the transistor is an N-type transistor.
